(19) United States
(12) Patent Application Publication
(10) Pub. No.: US 2004/0188842 A1
(43) Pub. Date: Sep. 30, 2004

(54) Interconnect structure

(75) Inventors: Hiroki Takewaka, Tokyo (JP); Takashi Yamashita, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/625,513

(22) Filed: Jul. 24, 2003

(30) Foreign Application Priority Data
Mar. 24, 2003 (JP) 2003-080228

(51) Int. Cl. H01L 23/48

(52) U.S. Cl. 257/758; 257/774

(57) ABSTRACT

A semiconductor device capable of suppressing current concentration in a region where a side surface portion of a lower-level interconnect layer and a via plug which is misaligned with the lower-level interconnect layer are connected, is provided. A lower-level interconnect layer (2) including an anti-reflective film (conductive film) (2b) in a top surface portion thereof is formed on an underlying insulating film (1). An interlayer insulating film (3) is formed so as to cover the lower-level interconnect layer (2) and the underlying insulating film (1). To allow for misalignment between a via plug (4) extending from a top surface of the interlayer insulating film (3) to the lower-level interconnect layer (2) and the lower-level interconnect layer (2), a high resistance layer (5) is provided in a side surface portion of the lower-level interconnect layer (2).

### BACKGROUND OF THE INVENTION

1. Field of the Invention

The present invention relates to an interconnect structure, and more particularly to an interconnect structure including a lower-level interconnect layer and a via plug connected to the lower-level interconnect layer.

2. Description of the Background Art

A conventional method of manufacturing a semiconductor device including a lower-level interconnect layer and a via plug connected to the lower-level interconnect layer will be described below (see column 5 and FIGS. 1 and 2 of Japanese Patent Application Laid-Open No. 10-209272, for example).

According to the conventional method, a lower-level interconnect layer having an anti-reflective film formed in each of top and bottom surface portions thereof is formed on an underlying insulating film. Subsequently, an interlayer insulating film is deposited so as to cover the underlying insulating film and the lower-level interconnect layer. Thereafter, a patterned resist is formed on the interlayer insulating film in order to form a contact hole. Then, a contact hole extending from a top surface of the interlayer insulating film to the lower-level interconnect layer is formed using the patterned resist.

It is very likely that there is left no sufficient margin for misalignment between the lower-level interconnect layer and the via plug, so that the contact hole as formed is located not within the lower-level interconnect layer due to misalignment during manufacture. In such a situation, a side surface portion of the lower-level interconnect layer is exposed in the contact hole.

After formation of the contact hole, a plasma process is carried out to form a reforming layer (high resistance layer) is formed in the exposed side surface portion of the lower-level interconnect layer. The formation of the reforming layer prevents the side surface portion of the lower-level interconnect layer from being transformed in an undesired manner due to a cleaning process using a chemical solution (wetting process) which is to be carried out in a subsequent step of removing the resist. Then, a wetting process is carried out to remove the resist.

Next, the reforming layer is removed by a reverse sputter cleaning process, to establish a current path in the side surface portion of the lower-level interconnect layer. Subsequently, a coating metal is formed on the contact hole. Finally, a metal is buried in the contact hole on which the coating metal is formed.

In a semiconductor device manufactured by the conventional method as described above, the side surface portion of the lower-level interconnect layer and the via plug are connected directly to each other. As such, it is probable that a contact resistance between the side surface portion of the lower-level interconnect layer and the via plug which are connected directly to each other is lower than a contact resistance between the top surface portion of the lower-level interconnect layer and the via plug which are connected with the anti-reflective film interposed therebetween.

In this configuration, current concentration occurs in a region where the side surface portion of the lower-level interconnect layer and the via plug are connected, which results in reduction of electromigration resistance in the corresponding region.

### SUMMARY OF THE INVENTION

It is an object of the present invention to provide an interconnect structure capable of suppressing current concentration in a region where a side surface portion of a lower-level interconnect layer and a via plug are connected to each other.

According to a first aspect of the present invention, an interconnect structure includes a substrate, an interconnect layer, an interlayer insulating film, a conductor and a high resistance layer. The interconnect layer is formed on the substrate and includes an interconnect body and a conductive film formed on the interconnect body. The interlayer insulating film is formed so as to cover the interconnect layer. The conductor is formed in a contact hole extending through the interlayer insulating film and includes a first region in contact with a top surface portion of the interconnect layer and a second region in contact with a side surface portion of the interconnect layer. The high resistance layer is formed in a side surface portion of the interconnect body which is in contact with the second region of the conductor.

It is possible to increase a contact resistance between the conductor and the side surface portion of the interconnect body, which allows current flow through a path including a region where the conductor and the top surface portion of the interconnect layer are connected to each other to be dominant in operating conditions. Accordingly, current concentration in the region where the conductor and the side surface portion of the interconnect layer are connected to each other can be suppressed, thereby to prevent electromigration resistance from being reduced due to current concentration.

According to a second aspect of the present invention, an interconnect structure includes a substrate, an interconnect layer, an interlayer insulating film and a conductor. The interconnect layer is formed on the substrate and includes an interconnect body and a conductive film formed on the interconnect body. The interlayer insulating film is formed so as to cover the interconnect layer. The conductor is formed in a contact hole extending through the interlayer insulating film and includes a first region in contact with a top surface portion of the interconnect layer and a second region connected to a side surface portion of the interconnect layer. An end face of the interconnect body is withdrawn relative to an end face of the conductive film. A portion of the interlayer insulating film is provided in a space formed because of withdrawal of the end face of the interconnect body relative to the end face of the conductive film. The interconnect body and the second region of the conductor are connected to each other with the portion of the interlayer insulating film interposed therebetween.

It is possible to increase a contact resistance between the conductor and the side surface portion of the interconnect body, which allows current flow through a path including a region where the conductor and the top surface portion of the interconnect layer are connected to each other to be dominant in operating conditions. Accordingly, current concentration in the region where the conductor and the side surface portion of the interconnect layer are connected to each other can be suppressed, thereby to prevent electromigration resistance from being reduced due to current concentration.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device according to a first preferred embodiment.

FIGS. 2 through 7 are sectional views of the semiconductor device according to the first preferred embodiment which is being manufactured.

FIG. 8 is a sectional view of a semiconductor device according to a second preferred embodiment.

FIGS. 9 through 13 are sectional views of the semiconductor device according to the second preferred embodiment which is being manufactured.

### DESCRIPTION OF THE PREFERRED EMBODIMENTS

Preferred Embodiments

Below, the present invention will be described in detail with reference to accompanying drawings which illustrate preferred embodiments of the present invention.

First Preferred Embodiment

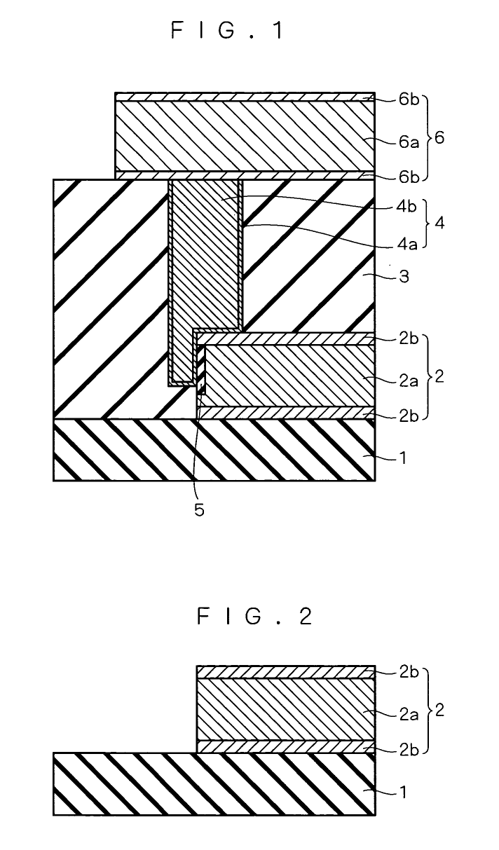

FIG. 1 is a diagrammatic sectional view of a semiconductor device according to a first preferred embodiment.

Referring to FIG. 1, an underlying insulating film 1 is formed on a semiconductor substrate which is not illustrated. Further, a lower-level interconnect layer 2 is formed on a predetermined portion of the underlying insulating film 1.

The lower-level interconnect layer 2 includes an interconnect body 2a made of aluminum or the like and anti-reflective films (which can be considered as a (first) conductive film) 2b made of TiN or the like which are formed on a top surface and a bottom surface of the interconnect body 2a, respectively.

A thickness of the interconnect body 2a is in a range of approximately 250 to 500 nm, while a thickness of each of the anti-reflective films 2b is in a range of approximately 60 to 120 nm. The thickness of each of the anti-reflective films 2b is determined to be in the foregoing range in order to allow one of the anti-reflective films 2b formed on the top surface of the interconnect body 2a to also function as an etch stop in a subsequent step of performing an etching process for forming a contact hole.

Further, an interlayer insulating film 3 is formed so as to cover the underlying insulating film 1 and the lower-level interconnect layer 2. Moreover, a contact hole extending from a top surface of the interlayer insulating film 3 to the lower-level interconnect layer 2 (in other words, extending through the interlayer insulating film 3) is formed in the interlayer insulating film 3, and a via plug (which can be considered as a conductor) 4 is formed within the contact hole.

The via plug 4 includes a barrier metal film (which can be considered as a second conductive film) 4a such as a TiN/Ti bilayer film, and a tungsten film 4b.

It is here noted that a wiring pitch has been reduced in recent years. For this reason, it is almost impossible to leave a sufficient margin for misalignment between the via plug 4 and the lower-level interconnect layer 2. Accordingly, it is likely that the via plug 4 as formed is misaligned with the lower-level interconnect layer 2 to be located not within the lower-level interconnect layer 2, as illustrated in FIG. 1. More specifically, in a configuration illustrated in FIG. 1, the via plug 4 is formed so as to be connected to both a side surface portion of the lower-level interconnect layer 2 (i.e, the interconnect body 2a) and a top surface portion of the lower-level interconnect layer 2 (i.e, the anti-reflective film 2b).

In other words, the via plug 4 has a first region in contact with the top surface portion of the lower-level interconnect layer 2 and a second region in contact with the side surface portion of the lower-level interconnect layer 2.

The first preferred embodiment exhibits its effects for the foregoing configuration in which the via plug 4 is misaligned with the lower-level interconnect layer 2 to be located not within the lower-level interconnect layer 2. Thus, the following description will be made on the assumption that the semiconductor device includes the foregoing configuration.

Referring back to FIG. 1, a high resistance layer 5 is formed in a portion of the interconnect body 2a to which the via plug 4 is connected.

Further, an upper-level interconnect layer 6 is provided so as to cover the interlayer insulating film 3 and the via plug 4. The upper-level interconnect layer 6 includes an interconnect body 6a made of aluminum or the like, and anti-reflective films 6b made of TiN or the like which are formed on a top surface and a bottom surface of the interconnect body 6a, respectively.

Next, a method of manufacturing the above-described semiconductor device will be described with reference to accompanying drawings.

First, the underlying insulating film 1 is formed on a semiconductor substrate which is not illustrated. Subsequently, one of the anti-reflective films 2b made of TiN or the like is formed by a sputtering process or the like. Then, the interconnect body 2a made of aluminum or the like is formed on a top surface of the anti-reflective film 2b previously formed, also by a sputtering process. Further, the other of the anti-reflective films 2b (which can be considered as the (first) conductive film) made of TiN or the like is formed on the top surface of the interconnect body 2a also by a sputtering process.

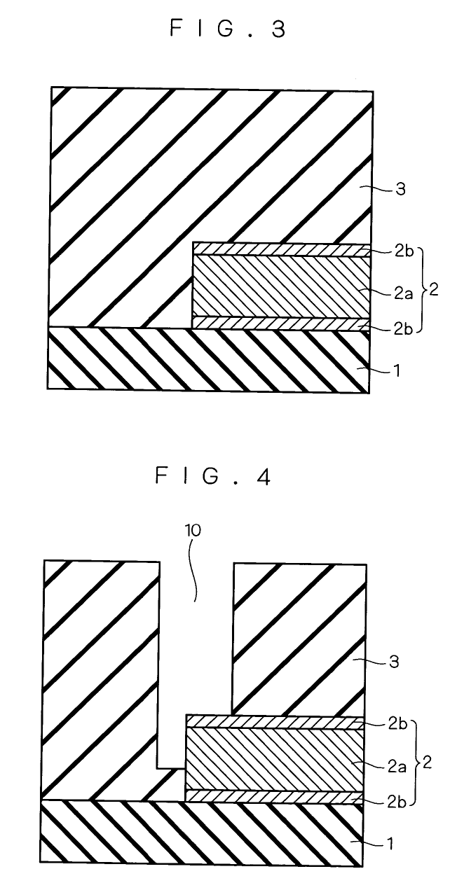

With the foregoing processes, the lower-level interconnect layer 2 (the anti-reflective film 2b/the interconnect body 2a/the anti-reflective film 2b) is completed on the predetermined portion of the underlying insulating film 1 (FIG. 2).

Preferably, one of the anti-reflective films 2b formed on the top surface of the interconnect body 2a is formed so as to have a thickness in a range of approximately 60 to 120 μm, in order to allow the anti-reflective film 2b to function as an etch stop in a later etching process.

After formation of the lower-level interconnect layer 2, the interlayer insulating film 3 is formed so as to cover the underlying insulating film 1 and the lower-level interconnect layer 2 by a CVD (Chemical Vapor Deposition) process or the like (FIG. 3).

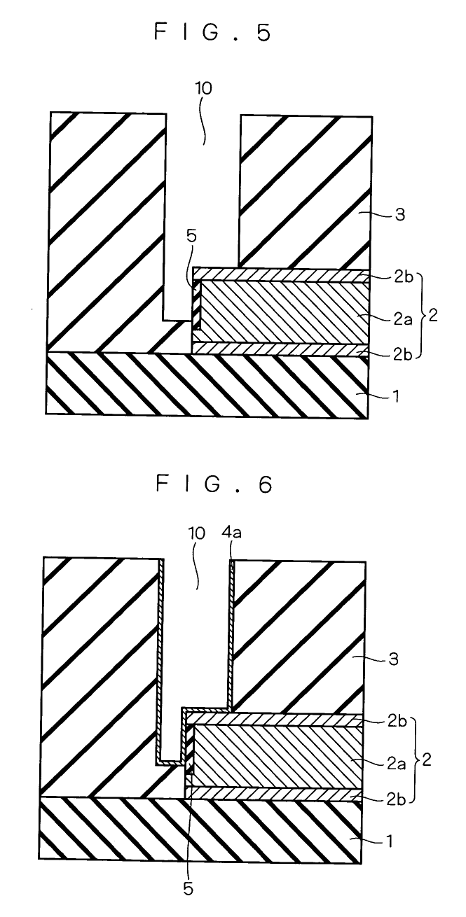

Then, a contact hole 10 extending from the top surface of the interlayer insulating film 3 to the lower-level interconnect layer 2 is formed by a typical lithographic process (FIG. 4). In this process involving an etching process, one of the anti-reflective films 2b formed on the top surface of the interconnect body 2a functions as an etch stop.

It is here noted that a wiring pitch has been reduced in recent years. For this reason, it is almost impossible to leave a sufficient margin for misalignment between the via plug 4 and the lower-level interconnect layer 2. Accordingly, it is likely that not only the top surface portion of the lower-level interconnect layer 2 (i.e., the anti-reflective film 2b) but also the side surface portion of the lower-level interconnect layer 2 (i.e., the interconnect body 2a) is exposed in the contact hole 10, as illustrated in FIG. 4. Thus, the following description will be made on the assumption that the foregoing configuration is provided by the previous processes.

The whole of the semiconductor device which is being manufactured and includes the configuration illustrated in FIG. 4 is exposed to an atmosphere of N₂, O₂ or the like, so that a side surface portion of the interconnect body 2a which is exposed in the contact hole 10 (i.e., the side surface portion of the lower-level interconnect layer 2) is nitrided or oxidized. As a result, the high resistance layer 5 is formed in the side surface portion of the interconnect body 2a (FIG. 5).

Specific procedures for formation of the high resistance layer 5 are as follows, for example. First, the whole of the semiconductor device which is being manufactured and includes the configuration illustrated in FIG. 4 is transferred into a vacuum chamber, and an N₂ or O₂ gas is introduced into the vacuum chamber at a pressure of approximately a few tens of Torr. Then, the semiconductor device is held in the foregoing state for approximately 30 seconds with the temperature thereof being kept in a range of approximately 100 to 300 degrees.

As a result, aluminum oxide (AlₓOₓ) or aluminum nitride (AlₓNₓ) with a thickness of approximately 20 nm is formed as the high resistance layer 5 in the side surface portion of the interconnect body 2a which is exposed in the contact hole 10.

Preferably, prior to formation of the high resistance layer 5, a sputtering process using argon or the like is carried out on the interconnect body 2a, to clean the exposed side surface portion of the interconnect body 2a. This process provides for increased uniformity of the high resistance layer 5 to be formed.

After formation of the high resistance layer 5 in the interconnect body 2a, the barrier metal film (which can be considered as the second conductive film) 4a such as a TiN/Ti bilayer film is formed on a bottom surface and a wall of the contact hole 10 by a sputtering process (FIG. 6).

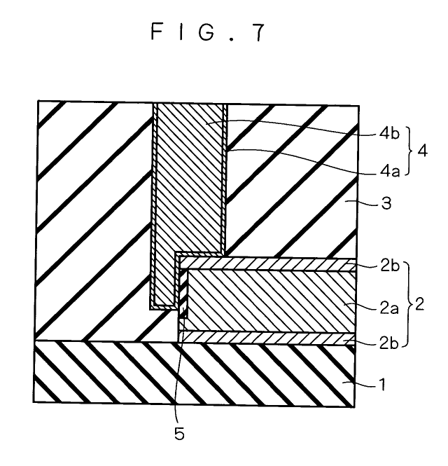

Subsequently, the contact hole 10 on which the barrier metal film 4a is formed is filled with tungsten by a CVD process using tungsten hexafluoride (WF₆) or the like as a source gas, to form the tungsten film 4b. Thereafter, an unnecessary portion of the tungsten which is provided on the interlayer insulating film 3 is removed by a dry etching process, a CMP (Chemical Mechanical Polishing) process or the like, to complete the via plug 4 connected to the lower-level interconnect layer 2 (FIG. 7).

As appreciated from illustration of FIG. 7, the via plug 4 is connected to the interconnect body 2a with the high resistance layer 5 interposed therebetween in the side surface portion of the lower-level interconnect layer 2, and is connected to the interconnect body 2a with one of the anti-reflective films 2b on the top surface of the interconnect body 2a interposed therebetween in the top surface portion of the lower-level interconnect layer 2.

Finally, the upper-level interconnect layer 6 (the anti-reflective film 6b/the interconnect body 6a/the anti-reflective film 6b) is formed so as to cover the interlayer insulating film 3 and the via plug 4 in the same manner as the lower-level interconnect layer 2.

By the foregoing processes, the semiconductor device as illustrated in FIG. 1 is manufactured. In the semiconductor device as illustrated in FIG. 1, the high resistance layer (a nitride layer or an oxide layer) 5 is formed in the side surface portion of the interconnect body 2a. The high resistance layer 5 has a resistance higher than that of the interconnect body 2a, which makes it possible to increase a contact resistance between the via plug 4 and the side surface portion of the lower-level interconnect layer 2. As a result, current flow through a path including the region where the via plug 4 and the top surface portion of the lower-level interconnect layer 2 are connected is dominant.

Hence, it is possible to suppress current concentration in the region where the via plug 4 and the side surface portion of the lower-level interconnect layer 2 are connected, to prevent electromigration resistance from being reduced due to occurrence of current concentration.

Further, to use an atmosphere of oxygen or nitrogen for forming the high resistance layer 5 results in formation of aluminum oxide or aluminum nitride, which provides for increased resistance of the high resistance layer 5 to be formed.

Moreover, the barrier metal film 4a may alternatively be a single layer of TiN, instead of a TiN/Ti bilayer film. When a single layer of TiN is employed as the barrier metal film 4a and the high resistance layer 5 is made of nitride, by carrying out a sputtering process using Ti during formation of the high resistance layer 5, it is possible to form the barrier metal film 4a of TiN on the contact hole at the same time as the high resistance layer 5 of nitride is formed in the interconnect body 2a, to reduce the number of processes to manufacture the semiconductor device.

Second Preferred Embodiment

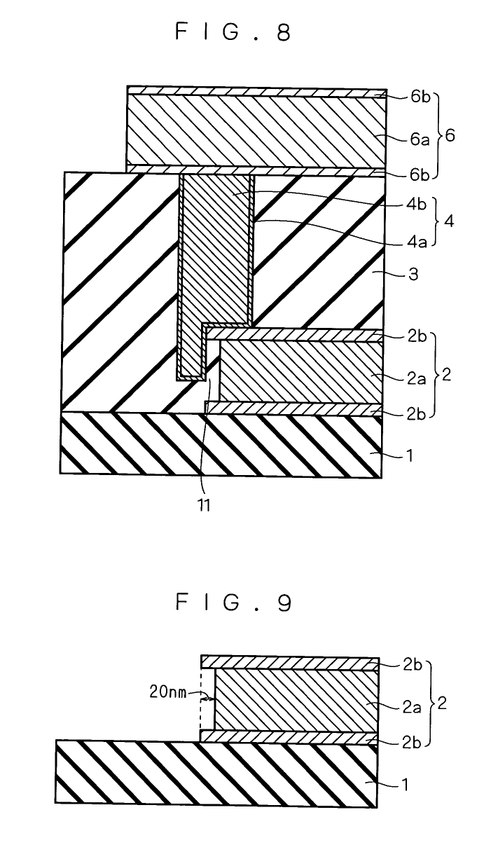

FIG. 8 is a diagrammatic sectional view of a semiconductor device according to a second preferred embodiment. Also the second preferred embodiment exhibits its effects for the above-described configuration in which the via plug (which can be considered as a conductor) 4 is misaligned with the lower-level interconnect layer 2 to be located not within the lower-level interconnect layer 2 because a sufficient margin for misalignment between the via plug 4 and the lower-level interconnect layer 2 can not be left due to a recent trend toward reduction of a wiring pitch.

In other words, the second preferred embodiment exhibits its effects when the via plug 4 has the first region in contact with a top surface portion of the lower-level interconnect layer 2 and the second region connected to a side surface portion of the lower-level interconnect layer 2.

A structure of the semiconductor device according to the second preferred embodiment (FIG. 8) is substantially identical to that of the semiconductor device according to the first preferred embodiment (FIG. 1) except the following respects.

Specifically, in the semiconductor device according to the first preferred embodiment, the via plug 4 is connected to the side surface portion of the lower-level interconnect layer 2 with the high resistance layer 5 which is made of oxide or the like and is formed in a side surface portion of the interconnect body 2a, interposed therebetween (FIG. 1). In contrast, in the semiconductor device according to the second preferred embodiment, the via plug 4 is connected to the side surface portion of the interconnect body 2a with an insulating film 11 interposed therebetween, as illustrated in FIG. 2.

The via plug 4 is connected directly to one of the anti-reflective films (which can be considered as a conductive film) 2b formed on a top surface of the interconnect body 2a in the semiconductor device according to the second preferred embodiment, similarly to the semiconductor device according to the first preferred embodiment.

The semiconductor device according to the second preferred embodiment is identical to the semiconductor device according to the first preferred embodiment with respect to the other structural features, and thus detailed description therefor is omitted herein.

Next, a method of manufacturing the above-described semiconductor device according to the second preferred embodiment will be described with reference to accompanying drawings.

First, the lower-level interconnect layer 2 including the interconnect body 2a and the anti-reflective films (which can be considered as a conductive film) 2b is formed on the underlying insulating film 1, in the same manner as described in the first preferred embodiment as illustrated in FIG. 2.

Subsequently, the side surface portion of the interconnect body 2a which has a predetermined width is removed by a wet etching process or a dry etching process (FIG. 9). At that time, no substantial influence is exerted on the anti-reflective films 2b.

Specific procedures for removal of the side surface portion of the interconnect body 2a are as follows, for example. First, assuming that the interconnect body 2a is made of aluminum, the whole of the semiconductor device which is being manufactured as illustrated in FIG. 2 is immersed into a chemical solution to which NH₄F (ammonium fluoride) is added, to cause NH4F to adhere to the interconnect body 2a. Subsequently, the semiconductor device being manufactured with NH₄F adhering thereto is immersed into H₂O (water), to cause NH₄F and H₂O to react each other.

In this manner, it is possible to remove the side surface portion of the interconnect body 2a without exerting substantial influence on the anti-reflective films 2b made of TiN. Preferably, the predetermined width of the side surface portion of the interconnect body 2a to be removed is equal to or less than approximately 20 μm, to ensure that the interlayer insulating film 3 is thereafter buried in a space formed as a result of removal of the side surface portion of the interconnect body 2a.

This results in formation of the insulating film 11 in the space, which has a width of approximately 20 nm in a later step. Such width enables the insulating film 11 to satisfactorily function as a high resistance layer.

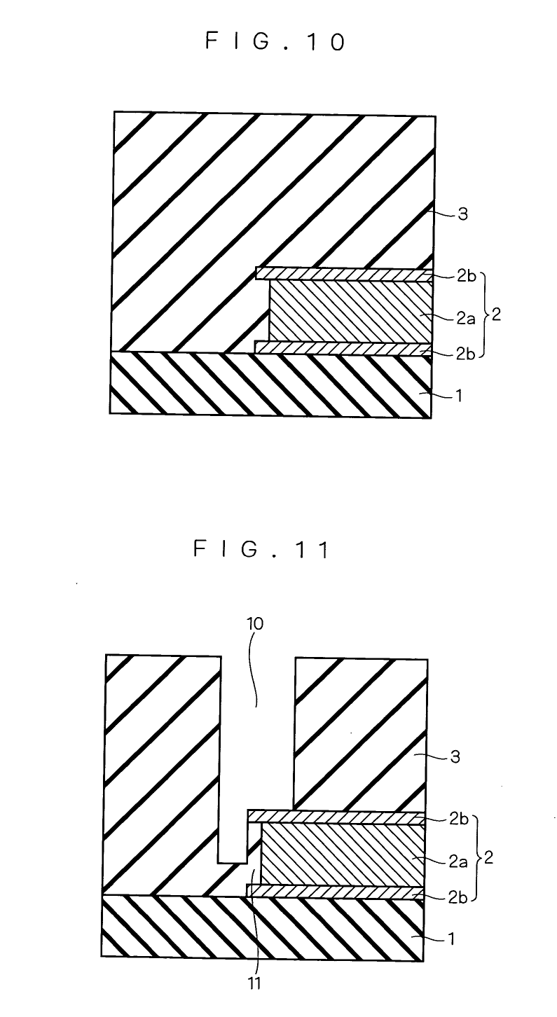

After removal of the side surface portion of the interconnect body 2a, the interlayer insulating film 3 is formed so as to cover the underlying insulating film 1 and the lower-level interconnect layer 2, as well as be buried in the space formed as a result of removal of the side surface portion of the interconnect body 2a, by a HDP (High Density Plasma)-CVD process or the like (FIG. 10). Employment of HDP-CVD process would ensure that the space formed as a result of removal of the side surface portion of the interconnect body 2a is completely filled with the interlayer insulating film 3 when the semiconductor device has dimensions used in this description of the second preferred embodiment.

Then, a typical lithographic process and an anisotropic etching process using the anti-reflective film 2b as an etch stop are carried out, to form the contact hole 10 extending from a top surface of the interlayer insulating film 3 to the lower-level interconnect layer 2 (FIG. 11).

It is here noted that the contact hole 10 as formed is likely to be misaligned with the lower-level interconnect layer 2 to be located not within the lower-level interconnect layer 2 as illustrated in FIG. 11, for the same reasons as given in the first preferred embodiment. Nevertheless, as one of the anti-reflective films 2b formed on the top surface of the interconnect body 2a functions like a “canopy” to prevent the insulating film 11 provided in the space formed as a result of removal of the side surface portion of the interconnect body 2a from being etched in the anisotropic etching process, the insulating film 11 remains included after formation of the contact hole 10.

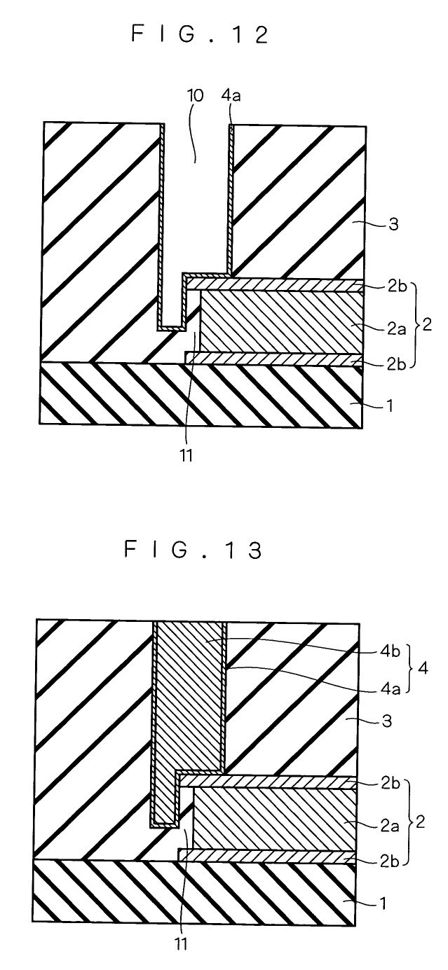

Thereafter, with the insulating film 11 kept provided in the space formed as a result of removal of the side surface portion of the interconnect body 2a, the barrier metal film 4a such as a TiN/Ti bilayer film is formed on a bottom surface and a wall of the contact hole 10 by a sputtering process (FIG. 12).

Subsequently, the contact hole 10 on which the barrier metal film 4a is formed is filled with the tungsten film 4b, and a process for planarizing the tungsten film 4b is carried out, thereby to complete the via plug 4 connected to the lower-level interconnect layer 2 (FIG. 13), in the same manner as described in the first preferred embodiment.

As appreciated from illustration of FIG. 13, the via plug 4 is connected to the interconnect body 2a with the insulating film 11 interposed therebetween in the side surface portion of the lower-level interconnect layer 2, and is connected to the interconnect body 2a with one of the anti-reflective films 2b on the top surface of the interconnect body 2a interposed therebetween in the top surface portion of the lower-level interconnect layer 2.

Finally, the upper-level interconnect layer 6 (the anti-reflective film 6b/the interconnect body 6a/the anti-reflective film 6b) is formed so as to cover the interlayer insulating film 3 and the via plug 4 (FIG. 8), as the lower-level interconnect layer 2 is formed.

By the foregoing processes, the semiconductor device as illustrated in FIG. 8 is manufactured. In the semiconductor device as illustrated in FIG. 8, the via plug 4 is connected to the side surface portion of the interconnect body 2a with the insulating film 11 interposed therebetween. This makes it possible to increase a contact resistance between the via plug 4 and the side surface portion of the lower-level interconnect layer 2. As a result, current flow through a path including the region where the via plug 4 and the top surface portion of the lower-level interconnect layer 2 are connected is dominant.

Hence, it is possible to suppress current concentration the region where the via plug 4 and the side surface portion of the lower-level interconnect layer 2 are connected, to prevent electromigration resistance from being reduced due to occurrence of current concentration.

It is noted that the structures and the manufacturing methods for a semiconductor device described above in the first and second preferred embodiments exhibit their effects for the configuration in which the via plug 4 as formed is misaligned with the lower-level interconnect layer 2 to be located not within the lower-level interconnect layer 2. However, the structures and the manufacturing methods described above will not affect operations of a semiconductor device as manufactured even if the foregoing configuration is not included therein.

Further, while the above description has been made to only a case where the interconnect structure according to the present invention is applied to a semiconductor device, the present invention is not limited to such case. The interconnect structure according to the present invention may be applied to an electronic device such as a liquid crystal device, for example.

While the invention has been shown and described in detail, the foregoing description is in all aspects illustrative and not restrictive. It is therefore understood that numerous modifications and variations can be devised without departing from the scope of the invention.

What is claimed is:

1. An interconnect structure comprising:
a substrate;
an interconnect layer which is formed on said substrate and includes an interconnect body and a conductive film formed on said interconnect body;
an interlayer insulating film formed so as to cover said interconnect layer;
a conductor which is formed in a contact hole extending through said interlayer insulating film and includes a first region in contact with a top surface portion of said interconnect layer and a second region in contact with a side surface portion of said interconnect layer; and
a high resistance layer formed in a side surface portion of said interconnect body which is in contact with said second region of said conductor.

2. The interconnect structure according to claim 1, wherein said high resistance layer is formed of said side surface portion of said interconnect body which is nitrided.

3. The interconnect structure according to claim 1, wherein said high resistance layer is formed of said side surface portion of said interconnect body which is oxidized.

4. An interconnect structure comprising:
a substrate;
an interconnect layer which is formed on said substrate and includes an interconnect body and a conductive film formed on said interconnect body;
an interlayer insulating film formed so as to cover said interconnect layer; and
a conductor which is formed in a contact hole extending through said interlayer insulating film and includes a first region in contact with a top surface portion of said interconnect layer and a second region connected to a side surface portion of said interconnect layer,
wherein an end face of said interconnect body is withdrawn relative to an end face of said conductive film,
a portion of said interlayer insulating film is provided in a space formed because of withdrawal of said end face of said interconnect body relative to said end face of said conductive film, and
said interconnect body and said second region of said conductor are connected to each other with said portion of said interlayer insulating film interposed therebetween.
